(19) United States
(12) Patent Application Publication
(10) Pub. No.: US 2024/0130046 A1
(43) Pub. Date: Apr. 18, 2024

(54) CAPACITOR

(71) Applicant: Nippon Telegraph and Telephone Corporation, Tokyo (JP)

(72) Inventors: Teruo Jo, Tokyo (JP); Munehiko Nagatani, Tokyo (JP); Hideyuki Nosaka, Tokyo (JP)

(21) Appl. No.: 18/546,526

(22) PCT Filed: Feb. 22, 2021
(86) PCT No.: PCT/JP2021/006570

§ 371 Date: Aug. 15, 2023

(51) Int. Cl. H05K 1/18

(52) U.S. Cl. CPC H05K 1/185; H01L 28/86; H05K 2201/10015

(57) ABSTRACT

A capacitor includes a pair of facing stacked electrodes connected to an electrical wiring from the outside. The stacked electrode includes a plurality of wiring layers and a via layer between the wiring layers. The stacked electrode includes combs and a comb connection portion connected to base ends of the combs. A dielectric is provided between one stacked electrode and the other stacked electrode. The comb of the other stacked electrode is disposed between the combs of the one stacked electrode.

### CROSS-REFERENCE TO RELATED APPLICATIONS

This application is a national phase entry of PCT Application No. PCT/JP2021/006570, filed on Feb. 22, 2021, which application is hereby incorporated herein by reference.

### TECHNICAL FIELD

The present invention relates to a capacitor used for a high frequency device.

### BACKGROUND

In electronic circuits, capacitors are essential components in order to design time constants, impedance, and the like of the circuits. Typically, in integrated circuits, metal-insulator-metal (MIM) capacitors in which dielectrics are sandwiched between two parallel plates are used.

In recent years, with the increases in speed of optical communication, wireless communication, and the like, circuits capable of coping with frequencies exceeding 100 GHz have become necessary. In these circuits, capacitors that have small capacitance values of about a few fF to 10 fF are necessary in some cases. However, in the MIM capacitors, capacitance values that can be implemented are limited to a few 10 fF or more due to limitations such as process accuracy.

As a capacitor capable of accurately implementing a capacitance value equal to or less than 10 fF through a normal manufacturing process, a comb-shaped capacitor illustrated in FIG. 8 has been proposed (Non Patent Document 1). In this comb-shaped capacitor, a wiring layer formed in a manufacturing process is used. An interval, a width, a shape, and the like of two wirings can be flexibly designed, and a capacitor that has a capacitance value equal to or less than 10 fF can also be designed.

### CITATION LIST

### Non Patent Literature

Non Patent Literature 1: D. Roy, J. H. Klootwijk, N. A. M. Verhaegh, H. H. A. J. Roosen and R. A. M. Wolters, “Comb capacitor structures for measurement of post-processed layers,” 2008 IEEE International Conference on Microelectronic Test Structures, Edinburgh, 2008, pp. 205-209, doi:10.1109/ICMTS.2008.4509339.

### SUMMARY

### Technical Problem

However, in the actually manufactured capacitor, there is not only a capacitance component but also a parasitic inductance component in the wiring or the like. This inductance component resonates with the capacitance component and causes self-resonance. An effective capacitance value of the capacitor increases toward a self-resonant frequency and gradually deviates from a capacitance value of a low frequency side. In order to design a circuit with high accuracy, it is typically preferable to limit a range of the capacitance of the capacitor to a range of 10% from the capacitance value of the low frequency side.

On the other hand, since the comb-shaped capacitor of the related art is designed and manufactured using only one type of wiring layer, a parasitic inductance is large and a resonance frequency is low. As a result, there is a problem that a usable frequency range for a capacitor is limited. FIG. 9 illustrates a simulation result of an effective capacitance value when a 10-fF comb-shaped capacitor (see FIG. 8) is designed. A frequency at which the capacitance of the capacitor is in the range of 10% from the capacitance value of the low frequency side remains at about 150 GHz.

### Solution to Problem

In order to solve the above-described problem, a capacitor according to embodiments of the present invention is a capacitor including a pair of facing stacked electrodes connected to electrical wirings from outside. Each of the stacked electrodes includes a plurality of wiring layers and a via layer between the wiring layers. Each of the stacked electrodes includes combs and a comb connection portion connected to base ends of the combs. A dielectric is provided between one of the stacked electrodes and the other stacked electrode. The combs of the other stacked electrode are disposed between the combs of the one stacked electrode.

### Advantageous Effects of Embodiments of Invention

According to embodiments of the present invention, it is possible to provide a capacitor capable of expanding a usable frequency range and coping with a high frequency circuit in a higher frequency band.

### BRIEF DESCRIPTION OF THE DRAWINGS

FIG. 1A is a bird's-eye view illustrating a configuration of a capacitor according to a first embodiment of the present invention.

FIG. 1B is a top view illustrating a configuration of the capacitor according to the first embodiment of the present invention.

FIG. 1C is a cross-sectional side view along the line IC-IC in the configuration of the capacitor according to the first embodiment of the present invention.

FIG. 2 is a view illustrating the method for manufacturing the capacitor according to the first embodiment of the present invention.

FIG. 3 is a view illustrating an effect of the capacitor according to the first embodiment of the present invention.

FIG. 4 is a top view illustrating an example of a configuration of a capacitor according to the first embodiment of the present invention.

FIG. 5A is a bird's-eye view illustrating a configuration of a capacitor according to a second embodiment of the present invention.

FIG. 5B is a cross-sectional front view along line VB-VB′ in the configuration of the capacitor according to the second embodiment of the present invention.

FIG. 6A is a bird's-eye view illustrating a configuration of a capacitor according to a third embodiment of the present invention.

FIG. 6B is a bird's-eye view illustrating a configuration of a capacitor according to the third embodiment of the present invention.

FIG. 6C is a view illustrating an arrangement of combs in the capacitor according to the third embodiment of the present invention.

FIG. 7 is a bird's-eye view illustrating a configuration of a capacitor according to a fourth embodiment of the present invention.

FIG. 8 is a bird's-eye view illustrating a configuration of a capacitor of the related art.

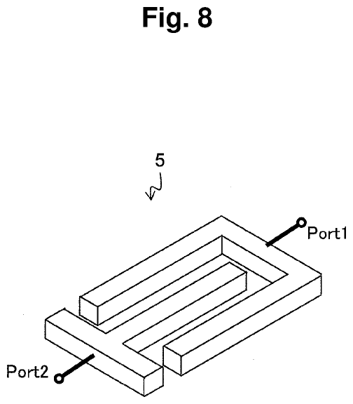

FIG. 9 is a view illustrating characteristics of a capacitor of the related art.

### DETAILED DESCRIPTION OF ILLUSTRATIVE EMBODIMENTS

### First Embodiment

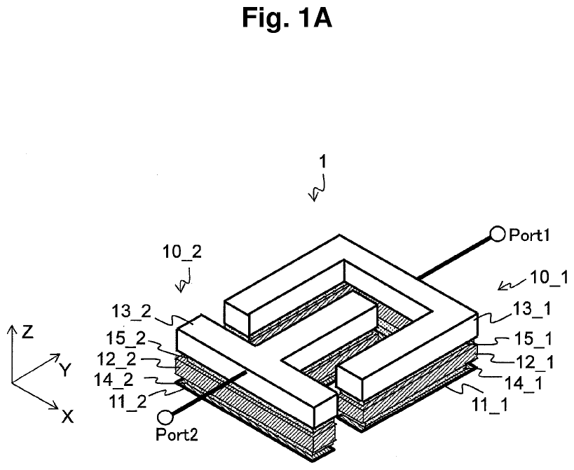

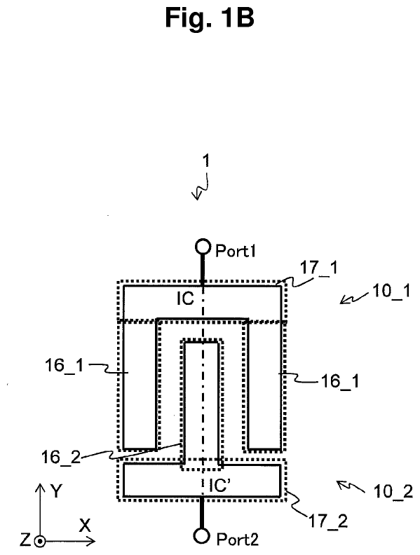

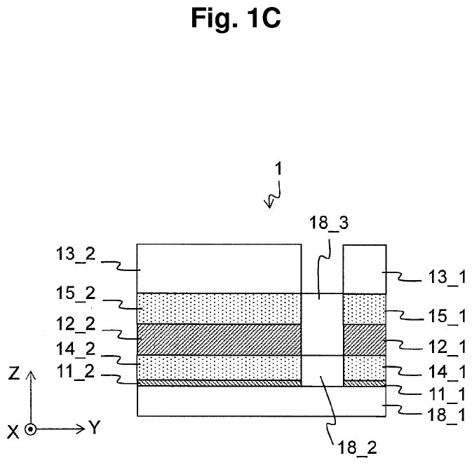

A capacitor according to a first embodiment of the present invention will be described with reference to FIGS. 1A to 4.

### Configuration of Capacitor

As illustrated in FIGS. 1A to 1C, a capacitor 1 according to the present embodiment includes a pair of stacked electrodes 10_1 and 10_2. The stacked electrodes 10_1 and 10_2 have three wiring layers and two via layers, and a via layer is provided between the wiring layers.

The three wiring layers are lower wiring layers 11_1 and 11_2, intermediate wiring layers 12_1 and 12_2, and upper wiring layers 13_1 and 13_2, are formed of metal, and are thicker in the order of the lower wiring layers 11_1 and 11_2, the intermediate wiring layers 12_1 and 12_2, and the upper wiring layers 13_1 and 13_2. The number of layers and the layer thickness are not limited thereto.

The two via layers are lower via layers 14_1 and 14_2 and upper via layers 15_1 and 15_2 and are formed of a metal. The lower via layers 14_1 and 14_2 are disposed between the lower wiring layers 11_1 and 11_2 and the intermediate wiring layers 12_1 and 12_2, respectively, and the upper via layers 15_1 and 15_2 are disposed between the intermediate wiring layers 12_1 and 12_2 and the upper wiring layers 13_1 and 13_2, respectively, to electrically connect the respective wiring layers.

As illustrated in FIG. 113, one stacked electrode 10_1 has an even number of combs 16_1, and base ends of the combs 16_1 are connected to a comb connection portion 17_1. The other stacked electrode 10_2 has an odd number of combs 16_2, and the base ends of the combs 16_2 are connected to a comb connection portion 17_2.

In the present embodiment, the X direction in the drawing is referred to as a “comb connection portion direction,” the Y direction in the drawing is referred to as a “comb direction,” and the Z direction in the drawing is referred to as a “vertical direction.” Therefore, the combs and the comb connection portion are connected in the Y direction, and the wiring layers and via layers are stacked in the Z direction. As described above, the direction in which the wiring layers and the via layers are stacked is perpendicular to a direction in which the combs and the comb connection portions are connected.

The capacitor 1 is configured such that the pair of stacked electrodes 10_1 and 10_2 face each other. Between the combs 16_1 of one stacked electrode 10_1, the comb 16_2 of the other stacked electrode 10_2 is disposed. Although not illustrated in FIGS. 1A and 113, dielectrics 18_1, 18_2, and 18_3 are disposed between the stacked electrodes 10_1 and 10_2 and around the stacked electrodes 10_1 and 10_2.

Here, the combs 16_2 of the other stacked electrode 10_2 are preferably disposed at centers between the combs 16_1 of the one stacked electrode 10_1.

The pair of stacked electrodes 10_1 and 10_2 are configured to be line-symmetric along a central line (In FIG. 1B, one-dot chain line IC-IC′) of the combs 16_2 at the center of the other stacked electrode 10_2 in the comb direction.

Electrical wirings from the outside (Port 1 and Port 2) are connected to the centers of the comb connection portions 17_1 and 17_2 of the upper wiring layers 13_1 and 13_2, respectively. The electrical wirings may be connected to the lower wiring layers 11_1 and 11_2 or the intermediate wiring layers 12_1 and 12_2.

### Method of Manufacturing Capacitor

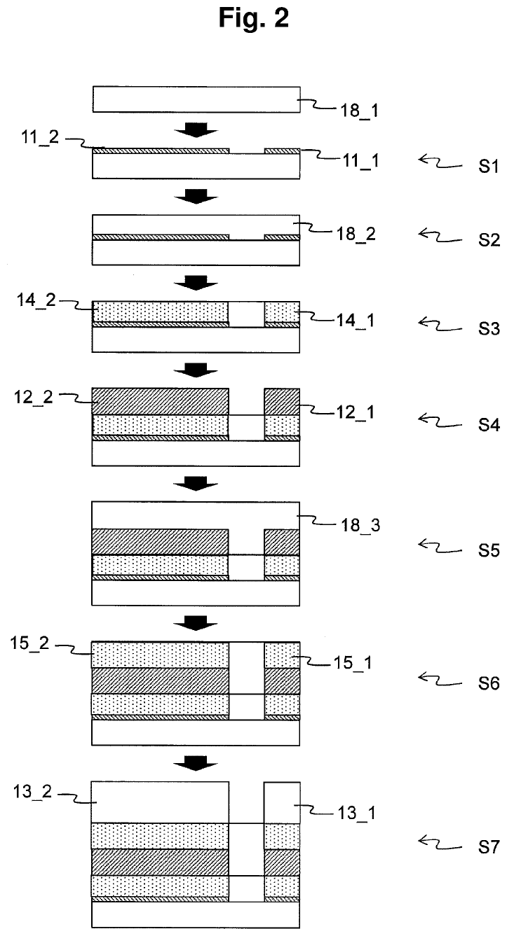

An example of a method of manufacturing the capacitor 1 according to the present embodiment will be described with reference to FIG. 2. As the manufacturing method, a normal semiconductor device manufacturing process is used.

First, the lower wiring layers 11_1 and 11_2 are formed on the dielectric 18_1 (step S1).

Subsequently, the dielectric 18_2 is formed to cover the lower wiring layers 11_1 and 11_2 (step S2).

Subsequently, the lower via layers 14_1 and 14_2 are formed in the dielectric 18_2 to be electrically connected to the lower wiring layers 11_1 and 11_2 (step S3).

Subsequently, the intermediate wiring layers 12_1 and 12_2 are formed to be electrically connected to the lower via layers 14_1 and 14_2 (step S4).

Subsequently, the dielectric 18_3 is formed to cover the intermediate wiring layers 12_1 and 12_2 (step S5).

Subsequently, the upper via layers 15_1 and 15_2 are formed in the dielectric 18_3 to be electrically connected to the intermediate wiring layers 12_1 and 12_2 (step S6).

Subsequently, the upper wiring layers 13_1 and 13_2 are finally formed to be electrically connected to the upper via layers 15_1 and 15_2 (step S7).

According to the above-described manufacturing method, for example, it is possible to manufacture a capacitor that has a configuration in which a comb-shaped wiring layer is formed in each of a plurality of layers of a multilayer printed board, and the comb-shaped wiring layers of the layers are connected by vias in the vertical direction.

The capacitor 1 according to the present embodiment can be formed on a semiconductor substrate such as a silicon substrate.

### Advantageous Effect of Capacitor

In the capacitor 1 according to the present embodiment, the capacitance per unit area increases more than in a configuration of the related art due to the configuration in which the number of wiring layers increases in the vertical direction. Therefore, it is possible to implement the same capacitance value with a capacitor that has a smaller size.

As a result, a wiring length can be reduced, and thus parasitic inductance can be reduced. Further, since the thickness of the wiring equivalently increases more than in a configuration that includes only one wiring layer, the parasitic inductance can be reduced. As described above, since a self-resonance frequency increases due to the reduction in the parasitic inductance, a usable frequency range of the capacitor according to the present embodiment can be expanded.

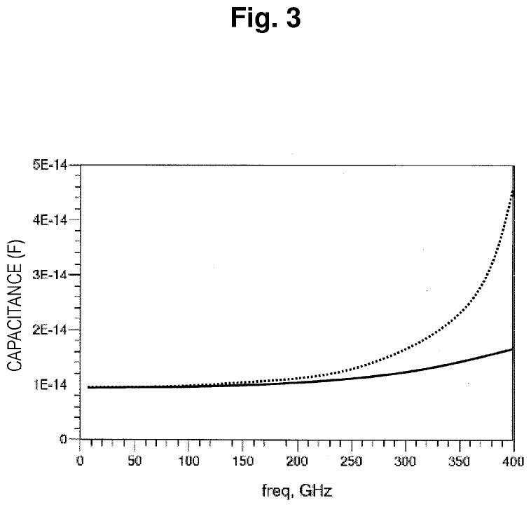

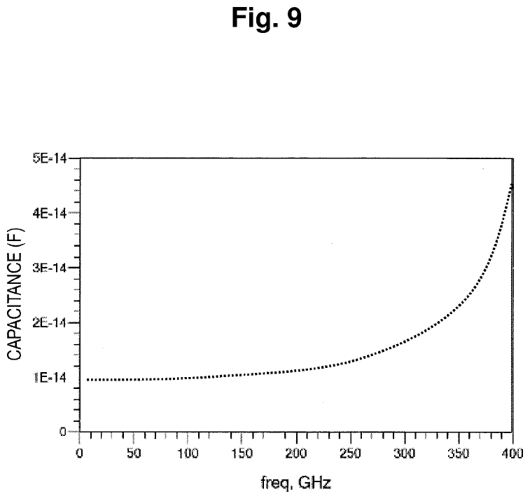

FIG. 3 illustrates a simulation result (indicated by a solid line in the drawing) of an effective capacitance value when a capacitor of 10 fF is designed using the configuration of the capacitor 1 according to the present embodiment. For comparison, a result (indicated by a dotted line as in FIG. 9) when a capacitor of 10 fF is designed using a configuration of the related art is also shown.

When the configuration of the capacitor 1 according to the present embodiment is used, a resonance frequency is higher than when a configuration of the related art is used. A frequency in a range of 10% from a capacitance value of the low frequency side is 220 GHz. It is possible to further expand a frequency range that can be used by 40% or more than when the configuration of the related art is used.

In this way, in the capacitor according to the present embodiment, it is possible to expand the usable frequency range, and thus the capacitor can be compatible with a high frequency circuit in a higher frequency band.

In connection between the capacitor according to the present embodiment and another component (a resistor, a transistor, or the like), connection is made at the center (midpoint) of the comb connection portion of the capacitor, and thus it is possible to increase the resonance frequency, and thus it is possible to expand the usable frequency range.

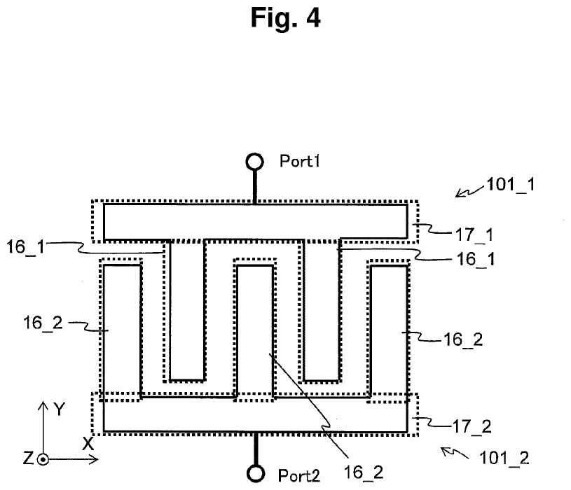

In the present embodiment, two combs 16_1 and one comb 16_2 (a total of three combs) face each other. However, the number of combs may be increased to achieve a larger capacitance value. At this time, for example, as illustrated in FIG. 4, by increasing the number of combs of each stacked electrode by an even number (increasing the total number of combs to be an odd number) to be line-symmetric along the central line in the comb direction of a central comb 16_2 in the stacked electrode 101_2 that has an odd number of combs, it is possible to maintain a wide frequency range and increase the capacitance value.

In the capacitor according to the present embodiment, it is preferable that a vertical and horizontal aspect ratio of an upper surface shape of each stacked electrode (including the combs and the comb connection portion) is in the range of 1:1 to 1:1.5 or 1:1 to 1.5:1. In other words, a ratio between a length of the capacitor in the comb direction and a length of the capacitor in the comb connection portion direction according to the present embodiment is preferably equal to or greater than 1/1.5 or equal to or less than 1.5.

In this configuration, it is possible to prevent a considerable increase in parasitic inductance component and to broaden the frequency range that can be used as a capacitor. Here, when the aspect ratio is out of the range, the parasitic inductance component increases, and the self-resonance frequency significantly decreases.

In the capacitor according to the present embodiment, for example, in a manufacturing process for an element (a resistor or a transistor) that can be connected to only a wiring of a specific layer in a multilayer printed board, the combs and the comb connection portion of the capacitor are formed in all the layers, and thus the capacitor and all the elements (the resistors or the transistors) can be easily connected. In this configuration, since the capacitance value per unit area also increases, the comb-shaped capacitor can be miniaturized.

In the present embodiment, the example in which the shapes of each wiring layer and each via layer are the same has been described, but the shapes are not limited to be completely the same, and may be substantially the same, or may be different. Each wiring layer and each via layer may not be configured to completely overlap when viewed from above. The via layer may have a plurality of columnar structures. Any shape and configuration may be used as long as the number of wiring layers increases in the vertical direction and the capacitance per unit area increases.

### Second Embodiment

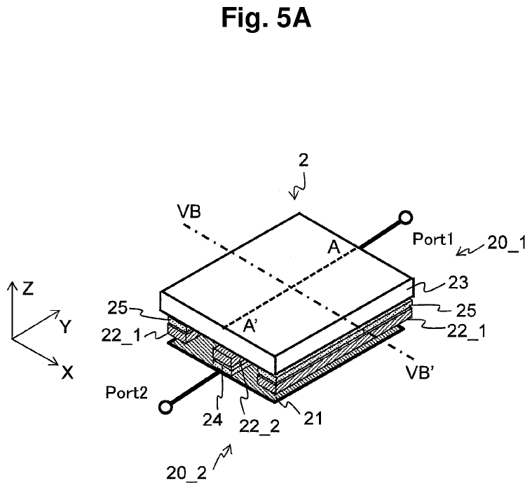

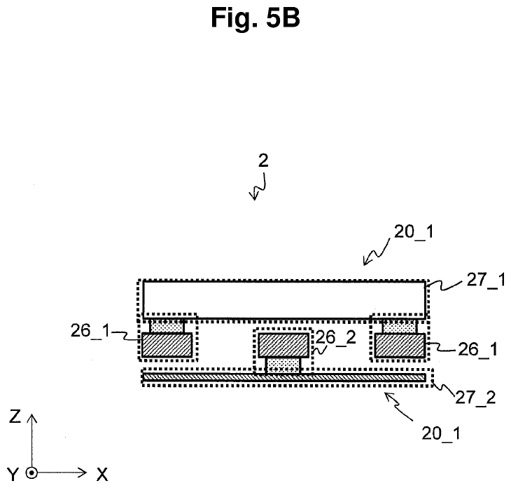

A capacitor according to a second embodiment of the present invention will be described with reference to FIGS. 5A and 5B. A capacitor 2 according to the present embodiment can be manufactured substantially similarly to the capacitor according to the first embodiment.

### Configuration of Capacitor

As illustrated in FIGS. 5A and 5B, the capacitor 2 according to the present embodiment includes a lower wiring layer 21, an intermediate wiring layer 22, an upper wiring layer 23, a lower via layer 24, and an upper via layer 25.

The three wiring layers are formed of metal, and the lower wiring layer 21, the intermediate wiring layer 22, and the upper wiring layer 23 are thicker in this order. The number of layers and the layer thickness are not limited thereto. The lower via layer 24 and the upper via layer 25 are formed of metal. Here, although not illustrated in FIGS. 5A and 5B, a dielectric is disposed between and around the wiring layer and the via layer.

The lower wiring layer 21 and the upper wiring layer 23 have planar shapes. In the present embodiment, the shape is rectangular, but the shape is not limited thereto.

The intermediate wiring layer 22 includes three wiring portions, and each wiring portion is a rectangular parallelepiped (rectangular when viewed from above). The wiring portions are arranged substantially in parallel. Two wiring portions 22_1 are connected to the upper wiring layer 23 via the upper via layer 25. On the other hand, one wiring portion 22_2 is connected to the lower wiring layer 21 via the lower via layer 24 and is disposed between the two wiring portions 22_1.

Here, the wiring portions 22_1 and 22_2 of the intermediate wiring layer are arranged on the same horizontal plane to be line-symmetric along the central line (a dotted line A-A′ in the drawing) of one wiring portion 22_2 in the wiring portion direction.

An electrical wiring from one outside (Port 1) is connected to a central portion of the upper wiring layer 23, and an electrical wiring from the other outside (Port 2) is connected to a central portion of the lower wiring layer 21.

In the above-described configuration, as illustrated in FIG. 5B, two wiring portions 22_1 and an upper via layer 25 form a comb 26_1, and are connected to an upper wiring layer 23 as a comb connection portion 27_1 to form one stacked electrode 20_1.

One wiring portion 22_2 and the upper via layer 24 form a comb 26_2, and are connected to the lower wiring layer 21 as a comb connection portion 27_2 to form the other stacked electrode 20_2.

In this configuration, when viewed from above, the combs 26_1 and 26_2 are arranged to be line-symmetric along the central line (a dotted line A-A′ in the drawing) of the central comb in the combs 26_2 of the other stacked electrode 20_2.

In the present embodiment, the Z direction in the drawing is referred to as a “vertical direction,” combs and a comb connection portion are connected in the vertical direction, and each wiring layer and each via layer are stacked in the vertical direction. As described above, a direction in which the wiring layer and the via layer are stacked and a direction in which the combs and the comb connection portion are connected are the same direction (parallel).

As described above, in the capacitor 2 according to the present embodiment, a pair of stacked electrodes 10_1 and 10_2, that is, one stacked electrode 20_1 and the other stacked electrode 10_2, are configured to face each other in the vertical direction.

### Advantageous Effect of Capacitor

In the capacitor 2 according to the present embodiment, it is possible to obtain the same advantageous effects as those of the first embodiment. By increasing the number of combs of each stacked electrode by an even number (increasing the total number of combs to be an odd number) to be line-symmetric along the central line in the comb direction of the central comb in the stacked electrode that has the odd number of combs, it is possible to maintain a wide frequency range and increase the capacitance value.

Further, in the capacitor 2 according to the present embodiment, since the width of the wiring layer is wide, inductance can be reduced.

In the present embodiment, an example in which the shapes of the wiring layer and the via layer in the comb are the same has been described. However, the shapes are not limited to be completely the same, and may be substantially the same, or may be different. The wiring layer and the via layer in the comb may not be configured to completely overlap each other when viewed from above. The via layer may have a plurality of columnar structures.

In the present embodiment, the example in which the comb (the wiring portion of the intermediate wiring layer) that has a rectangular upper surface shape is used has been described, but the present invention is not limited thereto. The upper surface shape of the comb may be a shape that has a curved portion or may be another shape. The example in which the combs are arranged to be line-symmetric has been described, but the present invention is not limited thereto. A shape and a configuration may be used in which the combs connected to the upper wiring layer (the comb connection portion) are arranged between the combs connected to the lower wiring layer (the comb connection portion), a pair of stacked electrodes are arranged to face each other in the vertical direction, and the capacitance per unit area increase.

### Third Embodiment

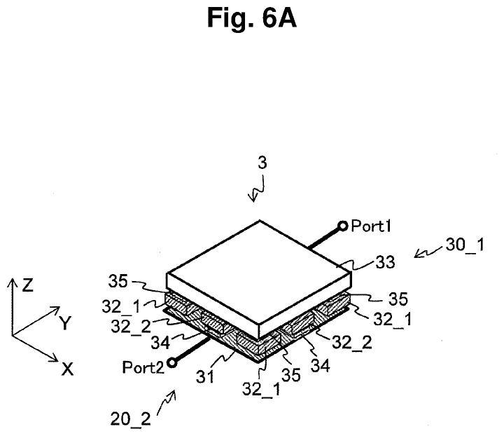

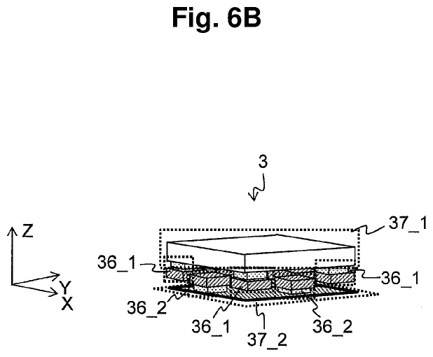

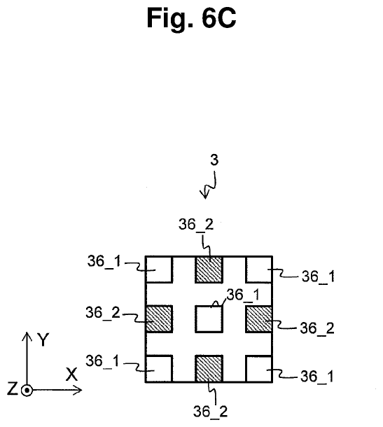

A capacitor according to a third embodiment of the present invention will be described with reference to FIGS. 6A to 6C. A capacitor 3 according to the present embodiment can be manufactured substantially similarly to the capacitor according to the first embodiment.

### Configuration of Capacitor

As illustrated in FIGS. 6A to 6C, the capacitor 3 according to the present embodiment includes a lower wiring layer 31, an intermediate wiring layer 32, an upper wiring layer 33, a lower via layer 34, and an upper via layer 35.

The three wiring layers are formed of metal, and the lower wiring layer 31, the intermediate wiring layer 32, and the upper wiring layer 33 are thicker in this order. The number of layers and the layer thickness are not limited thereto. The lower via layer 34 and the upper via layer 35 are formed of metal. Here, although not illustrated in FIGS. 6A to 6C, a dielectric is disposed between and around the wiring layer and the via layer.

The lower wiring layer 31 and the upper wiring layer 33 have planar shapes. In the present embodiment, the shape is rectangular, but the shape is not limited thereto.

The intermediate wiring layer 32 includes a plurality of wiring portions 32_1 and 32_2. Each of the wiring portions 32_1 and 32_2 is a rectangular parallelepiped that has a square upper surface shape and is periodically arranged. The wiring portion that has a square upper surface shape can prevent a considerable increase in a parasitic inductance component and expand a frequency range that can be used as a capacitor.

Five wiring portions 32_1 in the intermediate wiring layer 32 are connected to the upper wiring layer 33 via the upper via layer 35. On the other hand, four wiring portions 32_2 are connected to the lower wiring layer 31 via the lower via layer 34 and are disposed between the wiring portions 32_1 connected to the upper wiring layer 33.

Here, as illustrated in FIG. 6C, the wiring portions 32_1 and 32_2 of the intermediate wiring layer are arranged on the same horizontal plane to be point-symmetric along the center of one wiring portion 32_1.

An electrical wiring from one outside (Port 1) is connected to a central portion of the upper wiring layer 33 and an electrical wiring from the other outside (Port 2) is connected to a central portion of the lower wiring layer 31.

In the above-described configuration, as illustrated in FIG. 6B, the five wiring portions 32_1 and the upper via layer 35 form a comb 36_1 and are connected to the upper wiring layer 33 as the comb connection portion 37_1 to form one stacked electrode 30_1.

The four wiring portions 32_2 and the lower via layer 34 form the comb 36_2 and are connected to the lower wiring layer 31 as the comb connection portion 37_2 to form the other stacked electrode 30_2.

In this configuration, when viewed from above, the combs 36_1 and 36_2 are arranged to be point-symmetric along the center point of the central comb of combs 36_1 of one stacked electrode 30_1.

In the present embodiment, the Z direction in the drawing is referred to as a “vertical direction,” combs and a comb connection portion are connected in the vertical direction, and each wiring layer and each via layer are stacked in the vertical direction. As described above, a direction in which the wiring layer and the via layer are stacked and a direction in which the combs and the comb connection portion are connected are the same direction (parallel).

As described above, in the capacitor 3 according to the present embodiment, a pair of stacked electrodes 30_1 and 30_2, that is, one stacked electrode 30_1 and the other stacked electrode 30_2, are configured to face each other in the vertical direction.

### Advantageous Effect of Capacitor

According to the capacitor 3 of the present embodiment, even when the size of a via is limited, it is possible to obtain the same advantageous effects as those of the first and second embodiments. By increasing the number of combs of each stacked electrode by an even number (increasing the total number of combs to be an odd number) to be point-symmetric along the center of the central comb in the stacked electrode that has the odd number of combs, it is possible to maintain a wide frequency range and increase the capacitance value.

Further, in the capacitor 3 according to the present embodiment, since the width of the wiring layer is wide, the inductance can be reduced.

In the present embodiment, an example in which the shapes of the wiring layer and the via layer in the comb are the same has been described. However, the shapes are not limited to be completely the same, and may be substantially the same, or may be different. The wiring layer and the via layer in the comb may not be configured to completely overlap each other when viewed from above.

In the present embodiment, the example in which the comb (the wiring portion of the intermediate wiring layer) that has a square upper surface shape is used has been described, but the present invention is not limited thereto, and the upper surface shape of the comb may be a circular shape or another shape. The example in which the combs are arranged to be point-symmetric has been described, but the present invention is not limited thereto. A shape and a configuration may be used in which the combs connected to the upper wiring layer (the comb connection portion) are arranged between the combs connected to the lower wiring layer (the comb connection portion), a pair of stacked electrodes are arranged to face each other in the vertical direction, and the capacitance per unit area increase.

### Fourth Embodiment

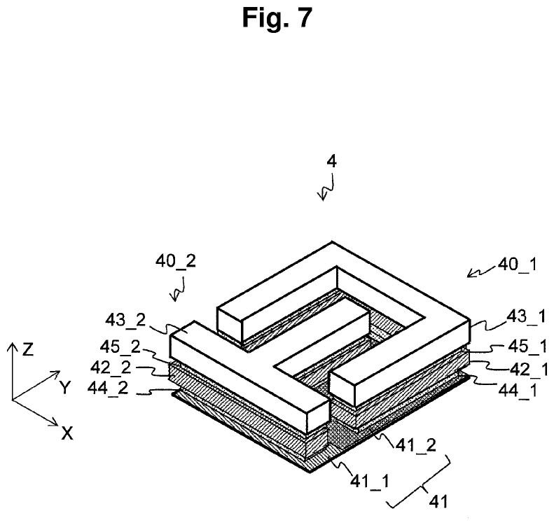

A capacitor according to a fourth embodiment of the present invention will be described with reference to FIG. 7. A capacitor 4 according to the present embodiment can be manufactured substantially similarly to the capacitor according to the first embodiment.

### Configuration of Capacitor

As illustrated in FIG. 7, the capacitor 4 according to the present embodiment has substantially the same configuration as that of the first embodiment, but differs in the configuration of the lower wiring layer.

In the capacitor 4, a metal-insulator-metal (MIM) capacitor is disposed in the lower wiring layer 41.

The MIM capacitor includes an MIM upper-layer metal 41_2, an MIM lower-layer metal 41_1, and a dielectric therebetween.

In one stacked electrode (Port1 side) 40_1, the upper wiring layer 43_1 is connected to the intermediate wiring layer 42_1 via the upper via layer 45_1, and the intermediate wiring layer 42_1 is connected to the MIM upper-layer metal 41_2 via the lower via layer 44_1.

In the other stacked electrode (Port1 side) 40_2, the upper wiring layer 43_2 is connected to the intermediate wiring layer 42_2 via the upper via layer 45_2, and the intermediate wiring layer 42_2 is connected to the MIM lower layer metal 41_1 via the lower via layer 44_2.

In this configuration, it is possible to implement a capacitance value greater than that of the MIM capacitor that has the same area as that of the capacitor according to the first embodiment.

In the capacitor according to the embodiment of the present invention, in the case of application to a multilayer circuit board, each wiring layer can be formed between layers of the multilayer circuit board, and each via layer can be formed in a layer of the multilayer circuit board. This configuration can be easily manufactured because the capacitor can be manufactured with a normal semiconductor device manufacturing process.

In the capacitor according to the embodiment of the present invention, the example in which three wiring layers are provided has been described, but the present invention is not limited thereto. A plurality of wiring layers may be provided. In this case, the upper wiring layer is the wiring layer located at the uppermost position, and the lower wiring layer is the wiring layer located at the lowermost position.

In the embodiment of the present invention, examples of the structure, dimensions, materials, and the like of the components have been described in the configuration of the capacitor, the manufacturing method, and the like, but the present invention is not limited thereto. The function of the capacitor may be exerted to obtain the advantageous effects.

### INDUSTRIAL APPLICABILITY

The present invention can be applied to devices and electronic circuits of devices used for optical communication, wireless communication, radar sensing, and the like.

### REFERENCE SIGNS LIST

1 Capacitor
10_1, 10_2 Stacked electrode
11_1, 11_2 Lower wiring layer
12_1, 12_2 Intermediate wiring layer
13_1, 13_2 Upper wiring layer
14_1, 14_2 Lower via layer
15_1, 15_2 Upper via layer
16_1, 16_2 Comb
17_1, 17_2 Comb connection portion
18_1, 18_2, 18_3 Dielectric

1.-8. (canceled)

9. A capacitor, comprising:
a pair of stacked electrodes connected to electrical wirings outside of the capacitor, wherein each of the pair of stacked electrodes includes a plurality of wiring layers and a via layer between the wiring layers, wherein each of the pair of stacked electrodes includes one or more combs and a comb connection portion connected to base ends of the one or more combs, wherein the one or more combs of a first electrode of the pair of stacked electrodes are disposed between the one or more combs of a second electrode of the pair of stacked electrodes; and
a dielectric between the first electrode of the pair of stacked electrodes and the second electrode of the pair of stacked electrodes.

10. The capacitor according to claim 9, wherein the electrical wirings are connected to a central portion of the comb connection portion.

11. The capacitor according to claim 9, wherein the plurality of wiring layers is disposed between layers of a multilayer circuit board, and wherein the via layers are disposed in layers of the multilayer circuit board.

12. The capacitor according to claim 11, wherein the one or more combs and the comb connection portion are formed in all layers of the multilayer circuit board.

13. The capacitor according to claim 9, wherein a direction in which the wiring layers and the via layer are stacked is perpendicular to a direction in which the one or more combs and the comb connection portion are connected.

14. The capacitor according to claim 9, wherein a ratio of a length in a comb direction to a length in a comb connection portion direction is equal to or greater than 1/1.5 and equal to or less than 1.5.

15. The capacitor according to claim 9, wherein a lowermost wiring layer among the plurality of wiring layers is an MIM capacitor.

16. The capacitor according to claim 9, wherein a direction in which the plurality of wiring layers and the via layer are stacked is parallel to a direction in which the one or more combs and the comb connection portion are connected.

17. The capacitor according to claim 16, wherein a first electrical wiring of the electrical wirings is connected to an uppermost wiring layer among the plurality of wiring layers.

18. The capacitor according to claim 17, wherein a second electrical wiring of the electrical wirings is connected to a lowermost wiring layer among the plurality of wiring layers.

19. A capacitor, comprising:
a first electrode comprising a first plurality of wiring layers and a first via layer between the first plurality of wiring layers, wherein the first plurality of wiring layers has a first comb and a first comb connection portion connected to the first comb;
a second electrode comprising a second plurality of wiring layers and a second via layer between the second plurality of wiring layers wherein the second plurality of wiring layers has a second comb, a third comb, and a second comb connection portion connect to the second comb and the third comb, and wherein the first comb extends between the second comb and the third comb; and
a dielectric between the first electrode and the second electrode.

20. The capacitor according to claim 19, wherein electrical wirings are connected to a central portion of the first comb connection portion or the second comb connection portion.

21. The capacitor according to claim 19, wherein a lowermost wiring layer among the first plurality of wiring layers is a first MIM capacitor.

22. The capacitor according to claim 19, wherein a lowermost wiring layer among the second plurality of wiring layers is a second MIM capacitor.

23. The capacitor according to claim 19, wherein a direction in which the first comb is connected to the first comb connection portion is perpendicular to a direction the plurality of first wiring layers are stacked.

24. The capacitor according to claim 19, wherein a direction in which the first comb is connected to the first comb connection portion is parallel to a direction the plurality of first wiring layers are stacked.

25. The capacitor according to claim 19, wherein electrical wirings are connected to an uppermost wiring layer among the first plurality of wiring layers or the second plurality of wiring layers.

26. The capacitor according to claim 19, wherein electrical wirings are connected to a lowermost wiring layer among the first plurality of wiring layers or the second plurality of wiring layers.
